(19) United States
(12) Patent Application Publication
(10) Pub. No.: US 2011/0101452 A1
(43) Pub. Date: May 5, 2011

(54) TRENCH GATE SEMICONDUCTOR DEVICE AND METHOD OF MANUFACTURING THEREOF

(75) Inventors: Jan Sonsky, Leuven (BE); Eero Saarnilehto, Leuven (BE)

(73) Assignee: NXP B.V., Eindhoven (NL)

(21) Appl. No.: 12/995,083

(22) PCT Filed: May 20, 2009
(86) PCT No.: PCT/IB09/52127

§ 371 Date: Jan. 7, 2011

(30) Foreign Application Priority Data
May 28, 2008 (EP) 08104137.8

(51) Int. Cl. H01L 29/78; H01L 21/76

(52) U.S. Cl. 257/334; 257/330; 438/425; 257/E29.262; 257/E21.54

(57) ABSTRACT

A trench-gate semiconductor device configuration is provided which is suitable for incorporation in integrated circuits, together with methods for its manufacture. A self-aligned drain region (12a) is provided below the device trench (18). The manufacturing methods include etching an initial trench into a semiconductor body (8), and annealing so as to cause migration of material such that a shallower trench with a cavity (36) below it are formed. The drain region is then formed in the cavity.

The present invention relates to trench-gate semiconductor devices. More particularly, it concerns such devices which are suitable for incorporation in integrated circuits.

Trench-gate transistors are commonly used as discrete components in system-in-package (SiP) products able to handle high voltages and/or high currents. It is though beneficial to integrate the vertical devices into integrated circuits and thereby replace SiP products with a system-on-chip approach.

Known methods for integrating trench-gate devices into integrated circuits involve formation of a buried doped layer to provide the drain region, followed epitaxial growth of a thick low doped silicon layer, and provision of connections to the buried layer by deep implants or trenches filled with conductive material. However, formation of the deep buried layer and subsequent growth of the epitaxial layer may have undesirable effects on other devices formed simultaneously on the same wafer.

The present invention provides a trench-gate semiconductor device, including a semiconductor body comprising a source region and a drain drift region of a first conductivity type, having therebetween a channel-accommodating region of an opposite, second conductivity type;

an insulated gate provided in a trench, the trench extending through the channel-accommodating region into the drain drift region; and

a drain region localised within the drain drift region, which is more highly doped than the drain drift region and provided below and in alignment with the trench.

The drain region may be located inside a buried tubular volume defined by the drain drift region, and surrounded by the drain drift region. The width of the tubular volume may be substantially the same as, or less than, that of the trench above it. The drain region may be self-aligned vertically with the trench above it, in accordance with manufacturing methods disclosed herein. More particularly, its vertical centre line in a plane perpendicular to the longitudinal axis of the tubular volume may be substantially aligned with the vertical centre line of the device trench.

In accordance with the manufacturing methods described herein, devices embodying the invention can be fabricated without necessarily requiring thick epitaxial or buried doped layers, making them particularly suitable for integration into planar integrated circuit processes.

The drain region may be formed of doped semiconductor material, for example by epitaxial growth or deposition. The connection to it may be formed of metal to reduce the resistance thereof.

Preferably, the device includes a plurality of trenches, wherein each trench has a respective localised drain region provided below and in alignment with it. Alternatively, as described herein, a drain region may be provided which extends laterally below two or more trenches, preferably defining a more substantially planar region, with its outer edges aligned with those of the outer trenches.

In accordance with embodiments of the invention, a buried isolation layer may be provided below the drain and the drain drift regions. Furthermore, an isolation trench may extend around the perimeter of the active area of the device and down to the isolation area, to fully isolate the device from the remainder of the substrate.

The invention further provides a method of manufacturing a semiconductor device embodying the invention, including the steps of etching an initial trench into a semiconductor body;

annealing so as to cause migration of material in the semiconductor body and transformation of the initial trench, such that the semiconductor body instead defines a shallower trench with a cavity below it; and

forming the drain region in the cavity.

A semiconductor surface migration technique is thereby employed to define a self-aligned drain region below the trench in a manner compatible with integrated circuit processing.

Preferably, the etching step comprises etching a plurality of initial trenches into the semiconductor body, and the annealing step causes transformation of the initial trenches, such that the semiconductor body instead defines corresponding shallower trenches with a common cavity extending laterally below them. This facilitates formation of a drain region in the cavity which extends below the plurality of trenches in the finished device.

In accordance with an alternative embodiment, the etching step comprises etching a plurality of initial trenches into the semiconductor body;

the annealing step causes transformation of the initial trenches, such that the semiconductor body instead defines corresponding shallower trenches with an upper and a lower cavity extending laterally below them;

the drain forming step comprises forming the drain region in the upper cavity; and

the method includes a further step of filling the lower cavity with an insulating material, for example by oxidation of its sidewalls or deposition, to form the buried isolation layer.

In a further variation, the etching step comprises etching a plurality of initial trenches into the semiconductor body;

the annealing step causes transformation of the initial trenches, such that the semiconductor body instead defines shallower trenches with respective upper and lower cavities below each trench;

the drain forming step comprises forming drain regions in the upper cavities; and

the method includes a further step of oxidizing the walls of the lower cavities such that the oxidized regions so formed merge to form the buried isolation layer.

Preferably, the shape of the initial trench is selected such that a predetermined trench shape is formed following transformation thereof during the semiconductor migration process. For example, the width of another portion of the initial trench may be greater than the width of a lower portion thereof. In one embodiment, this is achieved by tapering the walls of the trench over an upper portion thereof, such that its width decreases with depth along the tapered portion, whilst retaining a substantially vertical profile for the walls of the remaining, lower portion of the trench. Alternatively, an upper portion of the trench may have substantially parallel and vertical walls defining a first trench width, whilst a lower portion of the trench has substantially vertical parallel walls defining a second, narrower width.

Embodiments of the invention will now be described by way of example and with reference to the accompanying schematic drawings, wherein:

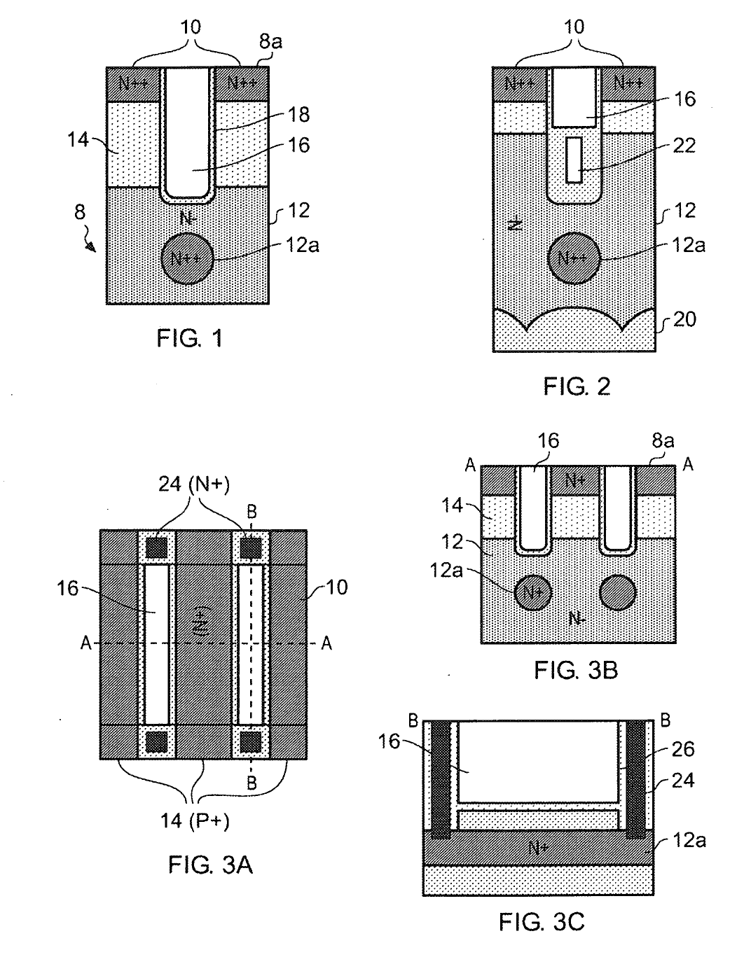

FIG. 1 is a cross-sectional side view of a trench-gate transistor embodying the invention;

FIG. 2 is a cross-sectional side view of a trench gate transistor embodying the invention and including dielectric isolation;

FIGS. 3A to 3C show a plan view, and two orthogonal cross-sectional side views along lines A-A and B-B as marked in FIG. 3A, of a trench-gate transistor embodying the invention;

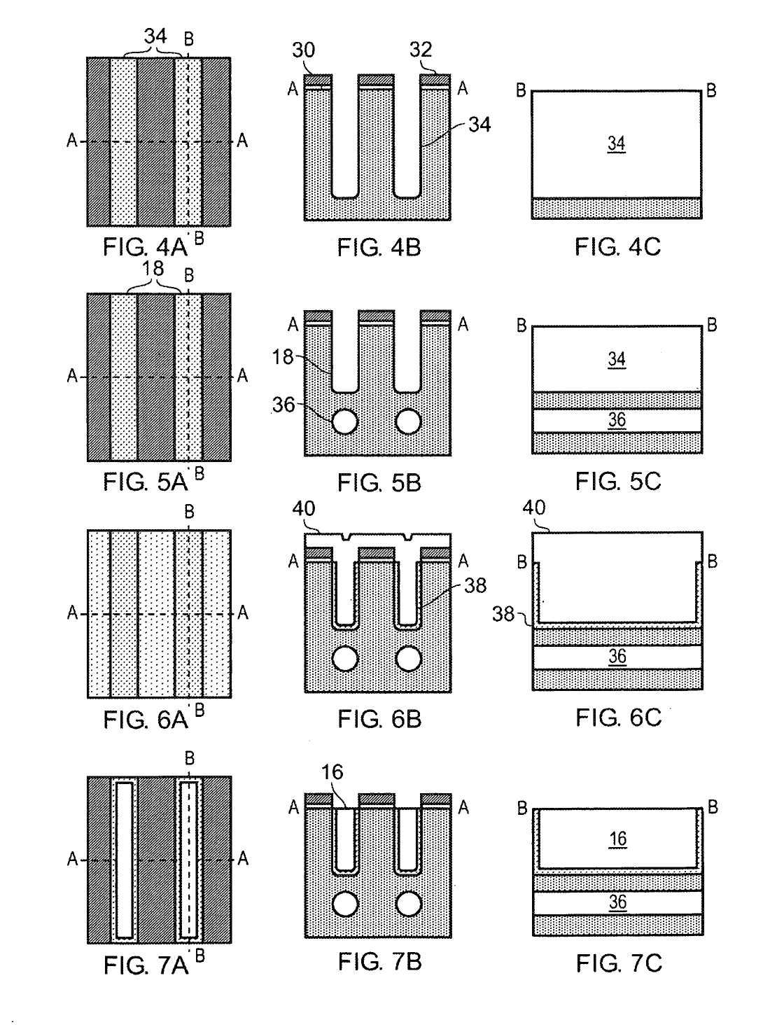

FIGS. 4A-C to 12A-C are views corresponding to those shown in FIG. 3 representing successive stages in the manufacture of a trench-gate transistor device in accordance with a method embodying the invention;

FIGS. 13A-C to 17A-C show views corresponding to those of FIG. 3 showing successive stages in the manufacture of a trench-gate transistor according to another embodiment of the invention;

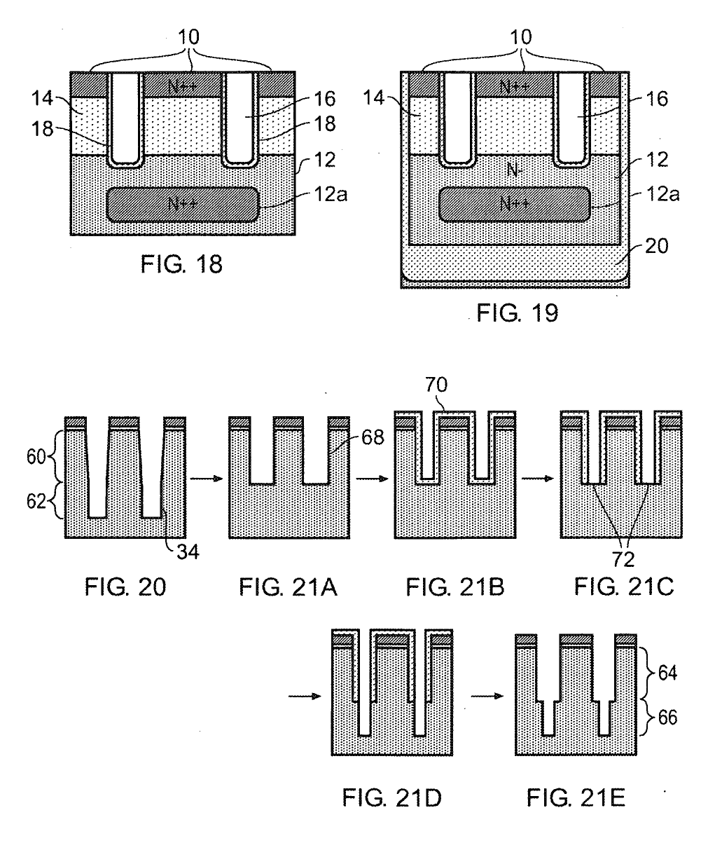

FIGS. 18 and 19 are cross-sectional side views of further trench-gate transistor configurations embodying the invention;

FIGS. 20 and 21A-E illustrate modification of the initial trench configuration;

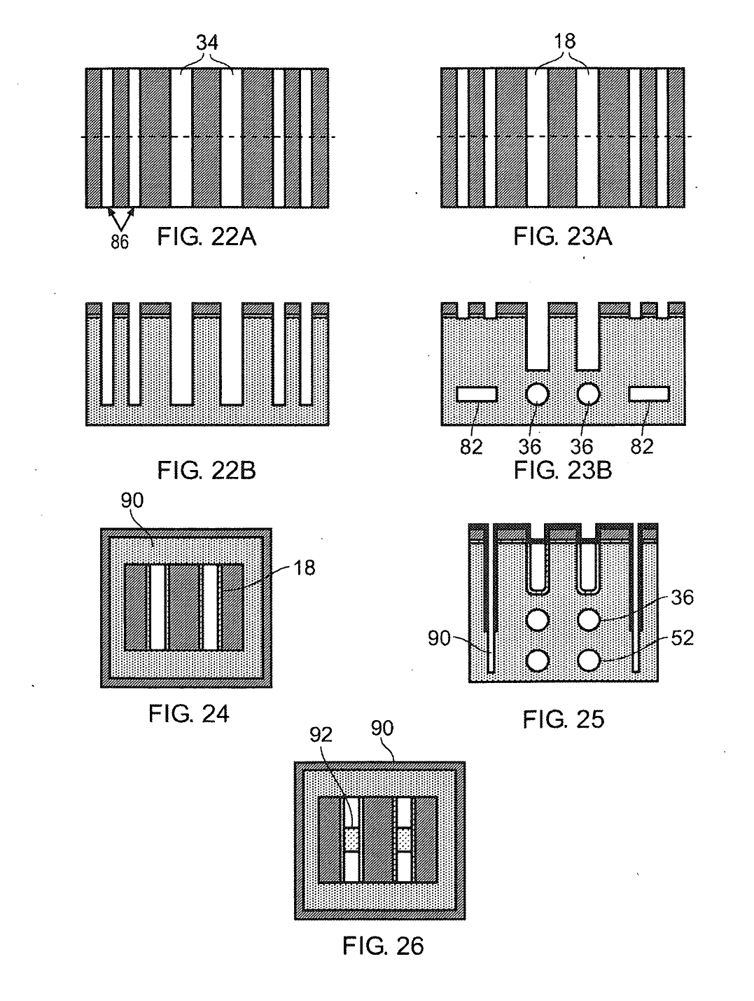

FIGS. 22A-B and 23A-B show top and cross-sectional side views of a semiconductor substrate to illustrate formation of dummy trenches before and after semiconductor migration, respectively; and

FIGS. 24 to 26 are plan, cross-sectional side and plan views, respectively, of a semiconductor substrate illustrating formation of connections to buried drain regions in accordance with embodiments of the invention.

It should be noted that the figures are diagrammatic and not drawn to scale. Relative dimensions and proportions of parts of these figures have been shown exaggerated or reduced in size, for the sake of clarity and convenience in the drawings. The same reference signs are generally used to refer to corresponding or similar features in modified and different embodiments.

The manufacturing processes and device configurations described herein utilise an effect referred to as “silicon surface migration”, as described for example in “Micro-structure transformation of silicon: A newly developed transformation technology for patterning silicon surfaces using the surface migration of silicon atoms by hydrogen annealing” by T. Sato et al, Jpn. J. Appl. Phys. 39, pp. 5033-5038, 2000, the contents of which are incorporated herein by reference. Thermal treatment of a silicon substrate at low pressure in a hydrogen ambient atmosphere has been found to lead to reorganisation of the surface of the silicon through silicon atom migration, so that the total surface energy is reduced. For example, appropriately shaped trenches or trench arrays can be transformed into buried cavities having a tubular or planar configuration, as described in “Empty-space-in-silicon technique for fabricating a silicon-on-nothing structure” by I. Mizushima et al, Appl. Phys. Let. 77(20), pp. 3290-3292, the contents of which are also incorporated herein by reference.

Processes have also been disclosed in which a trench is transformed into a shallower trench with a tubular cavity beneath, for example as described in “Trench transformation technology using hydrogen annealing for realising highly reliable device structure with thin dielectric films”, VLSI 1998 Conference Proceedings; the contents of which are incorporated herein by reference. According to methods described herein, such a structure is used to build a trench-gate field effect transistor having a configuration exemplified by FIG. 1.

A hydrogen anneal leads to transformation of an initial trench to form a buried tubular cavity below an essentially unaltered trench. A drain region is formed in the buried tube or pipe by epitaxy and filling with conductive material. In the device of FIG. 1, source and drain 10 and 12, 12a respectively, of a first conductivity type (n-type in this example) are separated by a channel-accommodating region 14 of the opposite, second conductivity type (i.e. p-type in this example in which case it may also be referred to as the p-body region). The drain comprises a low doped drift region 12 adjacent a drain region 12a.

A gate electrode 16 is present in a trench 18 which extends through the source and channel-accommodating regions 10, 14 into an underlying portion of the drift region 12. The source region 10 is contacted by a source electrode (not shown) at the top major surface 8a of the semiconductor body 8. Drain region 12a extends to the top major surface 8a outside the plane shown in FIG. 1 for contact by a drain electrode (not shown) as discussed further below. The application of a voltage signal to the gate 16 in the on-state of the device serves in a known manner for inducing a conduction channel in the region 14 and for controlling current flow in this channel between the source and drain 10 and 12, 12a.

By modifying the processing used to form the device shown in FIG. 1, two buried tubes made be formed under the trench, with the upper one defining the drain region and the lower one used to build an isolation layer 20 as shown in FIG. 2.

FIG. 2 also illustrates that the methods described herein are equally applicable to a range of trench-gate device configurations. As shown in the example of FIG. 2, a trenched field plate 22 is provided below the gate electrode. Similarly, a trench field plate may be provided which is an extension of the gate electrode into a portion of the trench which extends into the drift region 12.

FIGS. 3A to 3C represent plan and cross-sectional views of an n-channel trench-gate transistor manufactured according to the embodiment of the invention. Corresponding views of successive stages in the manufacture of this device are show in FIGS. 4 to 14 and are discussed below.

As shown in FIG. 3, conductive drain plugs 24 are provided in trenches 26 which extend from the top major surface 8a of the semiconductor body 8 down to the drain regions 12a to facilitate electrical connection to the drain regions at the top major surface. In this embodiment, the drain plug trenches 26 are provided in alignment with the gate trenches 18, at each end of gate electrode 16.

In the process stage of FIG. 4, oxide and nitride layers 30,32 have been deposited on top of the semiconductor body and patterned photolithographically to define a trench array. An etch process has then been carried out to form trenches 34.

Next, as shown in FIG. 5, a hydrogen anneal is carried out so as to cause silicon surface migration in the manner described above to form tubular cavities 36 below respective trenches 18, which trenches are reduced in depth relative to trenches 34. This is followed by oxidation by the trench sidewalls to form gate oxide layer 38 and a doped polysilicon layer 40 is then deposited conformally to arrive at the stage shown in FIG. 6. The polysilicon material is etched back to define the gate electrodes 16 (see FIG. 7).

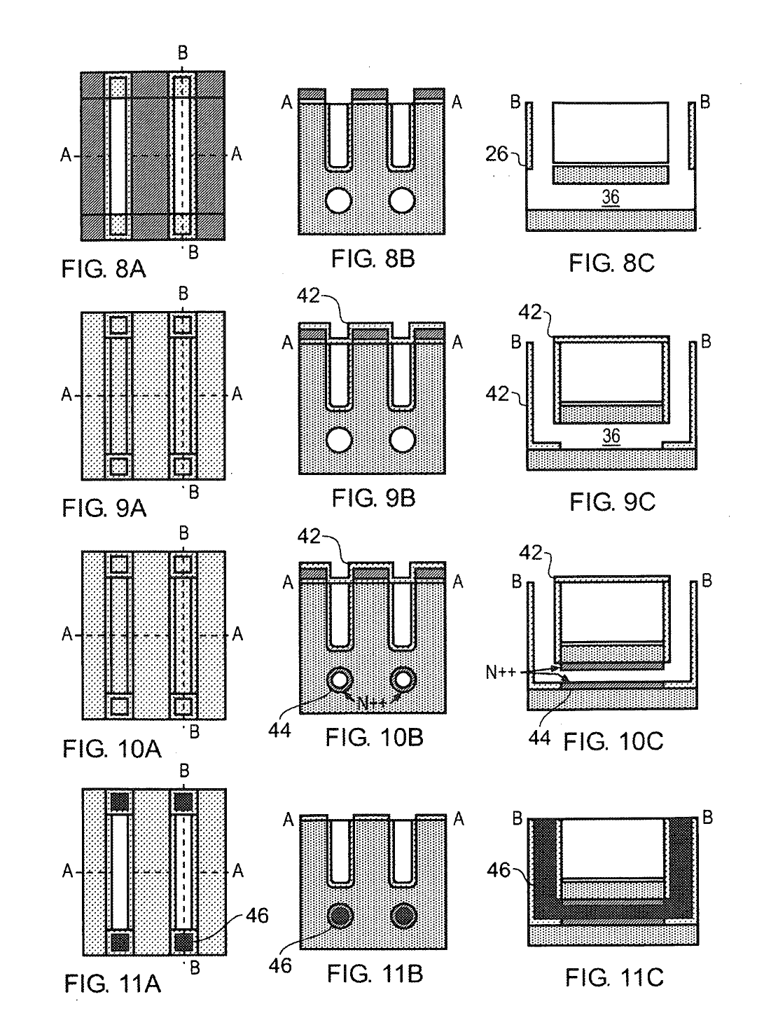

A mask is then defined over the semiconductor body which exposes polysilicon material at each end of the gate trenches. This material is then etched away to define drain plug trenches 26 which intersect with the horizontal drain tube 36, as shown in FIG. 8.

A non-conformal oxide deposition process (for example plasma enhanced CVD or high density plasma deposition) is carried out which forms an oxide layer 42 over the vertical walls of drain plug trench 26 and the portion of the base of tube 36 exposed by trenches 26. It can be seen that the walls of tube 36 beneath the gate electrode are not covered by oxide layer 42 in FIG. 9. Next, a layer of highly n-type doped epitaxial silicon 44 is selectively grown on the exposed walls of tube 36 to form a drain region extending around the walls of the tube (see FIG. 10). Then as shown in FIG. 11, electrically conductive material is deposited so as to fill tube 36 and trenches 26 and etched back to the top major surface 8a of the semiconductor body. Nitride layer is etched away. The conductive material, which may for example be doped polysilicon or a metal such as tungsten, forms a low-ohmic connection 46 to the buried drain region 44.

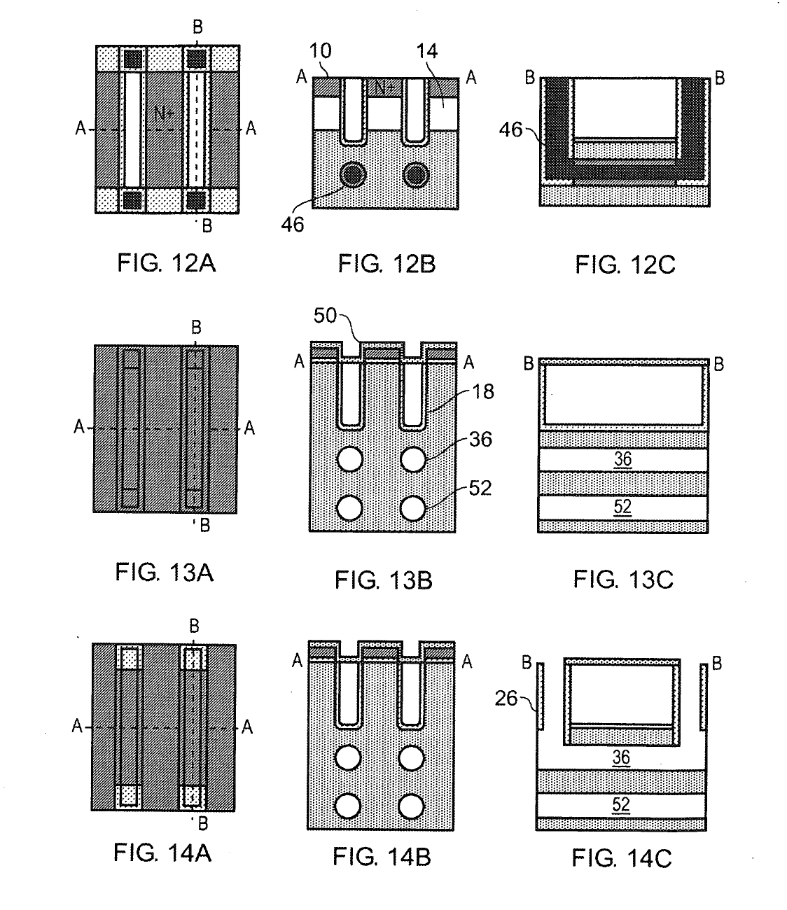

Next, the source and channel-accommodating regions 10, 14 are formed by successive implantations using an appropriately patterned photoresist mask (FIG. 12). Electrical connections to the source, channel accommodating and drain regions, together with the gate electrode 16, are then formed over the top major surface 8a of the semiconductor body in a known manner.

A process of the form embodied in FIGS. 4 to 12 above may be modified to form an isolated trench-gate transistor configuration. The initial stages correspond to FIGS. 4 to 7 and then the modified process continues in accordance with the stages shown in FIGS. 13 to 17.

The trench definition and hydrogen anneal stages of FIGS. 4 and 5 are also modified such that dual buried tubes 36, 52 are formed successively below each trench 18.

As shown in FIG. 13, a protective layer 50, of silicon nitride for example, is conformally deposited over the substrate. It serves to protect the gates 16 during later oxidation stages.

Drain plug trenches are then etched down to intersect with upper tube 36 at opposite ends of the gate electrodes 16 through windows defined photolithographically in a photoresist mask (FIG. 14).

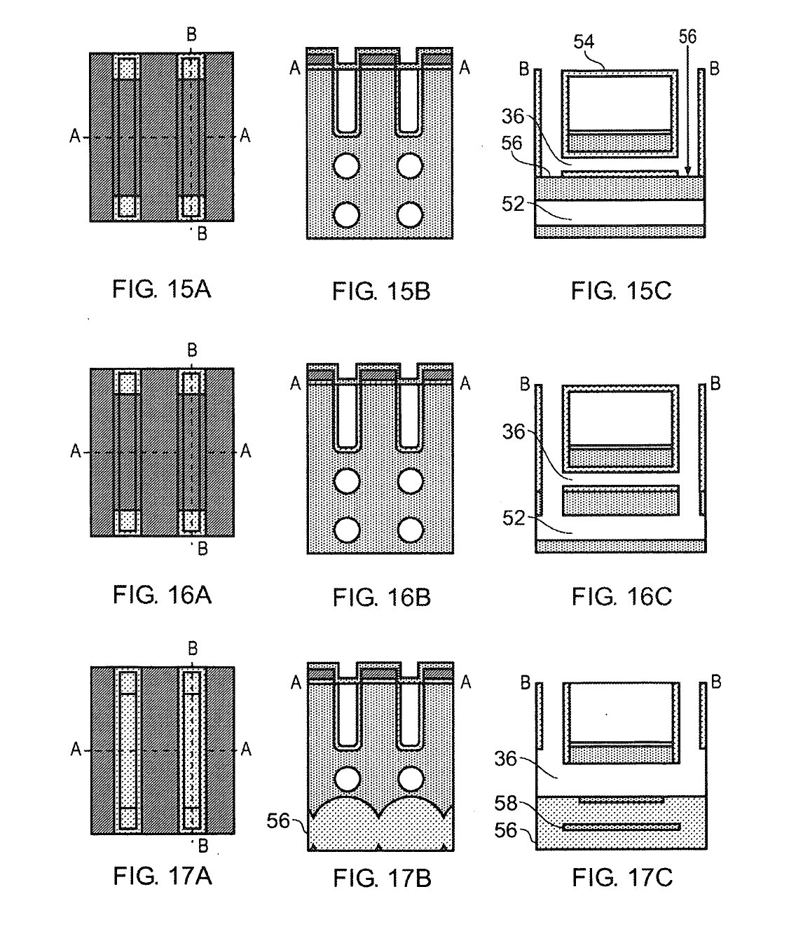

A layer 54 of an insulating material such as silicon nitride is uniformly deposited over the walls of trenches 26 and upper tube 36. An anisotropic etch process is carried out to open windows 56 at the base of each trench 26 (see FIG. 15).

A further etch is then carried out through the material of the drain drift region via windows 56. The drain plug trenches 26 are thereby extended downwardly to intersect with lower tube 52, as depicted in FIG. 16.

Next, the exposed walls of lower tube 52 are oxidised until the oxide regions so formed merge together to form a continuous buried oxide layer 56 (see FIG. 17). It is possible that a small void 58 may remain within layer 56. Nitride layer 54 is then etched away to arrive at the configuration shown at FIG. 17.

Further processing is then carried out in accordance with the method described above in relation to FIGS. 9 to 12.

In accordance with a further embodiment of the invention, the network of initial trenches etched as shown in FIG. 4 is configured such that buried planar cavities are obtained, instead of buried tubes, which extend laterally beneath a plurality of trenches. An example of a trench-gate transistor manufactured in this way is shown in FIG. 18. A planar, elongate drain region 12a is shown extending beneath and between two gate trenches 18.

As the entire active device area may be suspended during part of processing in accordance with this embodiment, to facilitate manufacture it may be desirable to split up the device into smaller cells.

An isolated trench-gate transistor configuration embodying the invention is depicted in FIG. 19. A buried isolation layer 20 is provided within a further plate-like or planar cavity created vertically below and spaced from drain region 12a. In this embodiment, the lower cavity may be filled using a conformal insulation layer deposition process instead of thermal oxidation. It can be seen that the resulting buried insulating layer 20 has a substantially uniform thickness underneath the entire device area.

The profile of the trenches initially etched into a substrate in accordance with embodiments of the invention may vary from a parallel sided configuration in order to adjust the cross-sectional profile of the trenches formed following silicon surface migration.

For example, as shown in FIG. 20, an upper portion 60 of each trench may be formed with a tapered profile such that its width decreases with depth down to a lower portion 62 having vertical, parallel sides.

Successive stages in the formation of an alternative initial trench profile are shown in FIG. 21. The resulting initial trenches shown in FIG. 21E have an upper portion 64 with parallel vertical sides, and a lower portion 66 with parallel vertical sides, but with a reduced distance therebetween.

As a first step, trenches 68 are etched into the top major surface of the semiconductor body, with their depth generally corresponding to the trench depth desired following the transformation process. A conformal layer 70 of oxide for example is deposited and an anisotropic etch carried out to form windows 72 at the base of each trench. A further trench etch is then carried out via the windows 72 as shown in FIG. 21D. Layer 70 is etched away to arrive at the configuration shown in FIG. 21E. Provision of narrower lower trench portions 66 is conducive to formation of buried tubes whilst leaving the upper wider trench portions 64 unchanged.

In some cases it may beneficial to provide one or more additional dummy trenches 80 spaced laterally from the device trenches, as depicted by way of example in FIG. 22. These dummy trenches are preferably narrower and more closely spaced together than the device trenches, so that the dummy trenches are largely removed or refilled during the transformation process, as shown in FIG. 33. Dummy tubular or planar cavities 82 are then formed alongside the cavities 36 beneath the device trenches 18.

These additional cavities 82 may be beneficial in formation of a fully isolated device (see below). These buried dummy-tubes or dummy-plates should be spaced apart from the buried cavities in the device area, so that they do not merge together.

Whilst drain plug trenches having a square cross-section in plan view are depicted in the process of FIGS. 4 to 12, in further embodiments, an elongate profile in plan view may be employed, which extends transversely across the device trench array. For example, in the isolated device configuration shown in FIG. 24, the drain plug trench 90 may extend around the entire device active area. The portion of the trench extending parallel to the device trenches 18 is narrower than the portions running transversely with respect to the device trenches. This approach facilities full device isolation using a single plug trench mask. Subsequent processing steps are similar to those described above in relation to the isolated embodiment of FIGS. 13 to 17.

A cross-sectional view of the semiconductor body prior to oxidation to form the isolation region is shown in FIG. 25. During oxidation, the silicon sidewall between the drain plug trench and the cavities 52 is fully oxidised. During the subsequent non-conformal oxide deposition step (corresponding to FIG. 9 above), the narrower drain plug trenches parallel to the device trenches are completely filled, so that no conductive material is deposited there during the following process steps. This part of the drain plug trench acts as an isolation-surround trench. The dummy-approach described with reference to FIGS. 22 and 23 above may conveniently be used in combination with the surrounding drain plug trench to narrow the silicon sidewalls that need to be oxidised. It is necessary to ensure that these dummy-cavities do not merge with the cavities in the device area in this case to avoid separation of the device area from the remainder of the semiconductor body.

An alternative configuration for the drain plug trenches is shown in FIG. 26. In this case, the drain connections are formed in the middle of the device trenches via drain plug trenches 92. It is preferable to have the (high voltage) drain connection towards the centre of the device.

In some cases, it may be preferable to enlarge the size of the drain cavity. This may be conveniently achieved by an isotropic etch or another hydrogen anneal prior to the stages shown in FIG. 17 and/or 10 above.

It will be appreciated that whilst the drain region is shown in the embodiments discussed above as having the same conductivity type (n-type in these examples) as the drain drift region, the drain region may instead be of the opposite conductivity type (p-type in these examples) to provide a vertical IGBT.

The device trenches of the configurations shown in the drawings have an elongate stripe geometry. The techniques described herein are also applicable to other, cell geometries, such as a square or close-packed hexagonal geometry.

Instead of forming the conductive gate of the device from doped polycrystalline silicon, other known gate technologies may be used in particular devices, This, for example, additional material may be used for the gate, such as a thin metal layer that forms a silicide with the polycrystalline silicon material. Alternatively, the whole gate may be formed of metal instead of polycrystalline silicon. In place of an insulating gate structure, so-called Schottky gate technologies may be used. In this case, a gate dielectric layer is absent and the conductive gate is of a metal that forms a Schottky barrier with the channel-accommodating region.

The particular examples described above are n-channel devices. It would be appreciated that, by using opposite conductivity type dopants, a p-channel device can be manufactured in accordance with the invention.

From reading the present disclosure, other variations and modifications will be apparent to persons skilled in the art. Such variations and modifications may involve equivalent and other features which are already known in the art, and which may be used instead of or in addition to features already described herein.

Although claims have been formulated in this application to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The applicants hereby give notice that new claims may be formulated to such features and/or combinations of such features during the prosecution of the present application or of any further application derived therefrom.

1. A trench-gate semiconductor device, including:
a semiconductor body (8) comprising a source region (10) and a drain drift region (12) of a first conductivity type, having therebetween a channel-accommodating region (14) of an opposite, second conductivity type;
an insulated gate (16) provided in a trench (18), the trench extending through the channel-accommodating region into the drain drift region; and
a drain region (12a) localised within the drain drift region, which is more highly doped than the drain drift region and provided below and in alignment with the trench.

2. A device of claim 1 including a plurality of trenches (18), wherein each trench has a respective localised drain region (12a) provided below and in alignment therewith.

3. A device of claim 1 including a plurality of trenches (18), wherein a drain region (12a) extends laterally below at least two trenches.

4. A device of any preceding claim, wherein the semiconductor body includes a buried isolation layer (20) below the drain drift region (12).

5. A device of claim 4, wherein the semiconductor body includes an isolation trench (90) which extends around the perimeter of the active area of the device and down to the isolation layer (20).

6. A method of manufacturing a semiconductor device of any preceding claim, including the steps of:
etching an initial trench (34) into a semiconductor body (8);
annealing so as to cause migration of material in the semiconductor body and transformation of the initial trench, such that the semiconductor body instead defines a shallower trench (18) with a cavity (36) below it; and
forming the drain region (12a) in the cavity.

7. A method of claim 6, wherein the etching step comprises etching a plurality of initial trenches (34) into the semiconductor body (8), and the annealing step causes transformation of the initial trenches, such that the semiconductor body instead defines corresponding shallower trenches (18) with a cavity (36) extending laterally below them.

8. A method of claim 6, wherein:
the etching step comprises etching a plurality of initial trenches (34) into the semiconductor body;
the annealing step causes transformation of the initial trenches, such that the semiconductor body instead defines corresponding shallower trenches (18) with an upper and a lower cavity (36,52) extending laterally below them;
the drain forming step comprises forming the drain region (12a) in the upper cavity (36); and
the method includes a further step of filling the lower cavity (52) with an insulating material to form the buried isolation layer (20).

9. A method of claim, wherein:
the etching step comprises etching a plurality of initial trenches (34) into the semiconductor body (8);
the annealing step causes transformation of the initial trenches, such that the semiconductor body instead defines shallower trenches (18) with respective upper and lower cavities (36,52) below each trench;
the drain forming step comprises forming drain regions (12a) in the upper cavities (36); and
the method includes a further step of oxidizing the walls of the lower cavities (52) such that the oxidized regions so formed merge to form the buried isolation layer (20).

10. A method of any of claims 6 to 9, wherein the width of an upper portion (60) of the or each initial trench (34) is greater than the width of a lower portion (62) thereof.

11. A method of claim 10, wherein the or each initial trench (34) is tapered over at least an upper portion (60) thereof, such that its width decreases with depth along the tapered portion.

12. An integrated circuit device including a semiconductor device of any of claims 1 to 5 or including a semiconductor device manufactured in accordance with a method of any of claims 6 to 11.
